(19) United States
(12) Patent Application Publication
(10) Pub. No.: US 2026/0190943 A1
(43) Pub. Date: Jul. 2, 2026

(54) WAFER-PROCESSING SHEET AND METHOD FOR MANUFACTURING A SEMICONDUCTOR DEVICE

(71) Applicant: DISCO CORPORATION, Tokyo (JP)

(72) Inventors: Masamitsu Kimura, Tokyo (JP); Koshiro Suzuki, Tokyo (JP); Norihisa Arifuku, Tokyo (JP)

(21) Appl. No.: 19/385,561

(22) Filed: Nov. 11, 2025

(30) Foreign Application Priority Data
Nov. 28, 2024 (JP) 2024-206827

(51) Int. Cl. H01L 21/683; H01L 21/02; H01L 21/78

(52) U.S. Cl. CPC H10P 72/74; H10P 54/00; H10P 70/237; H10P 90/123; H10P 90/124; H10P 72/7412; H10P 72/7416; H10P 72/7422; H10P 72/7442

(57) ABSTRACT

A wafer-processing sheet includes a water-soluble resin layer formed of a water-soluble resin, and a base layer formed of a resin sheet covering one side of the water-soluble resin layer and having tackiness on a surface thereof on a side toward the water-soluble resin layer under a predetermined condition.

### CROSS REFERENCE TO RELATED APPLICATION

This application is based upon and claims the benefit of priority from the prior Japanese Patent Application No. 2024-206827 filed on Nov. 28, 2024; the entire contents of which are incorporated herein by reference.

### FIELD

The present disclosure relates to a wafer-processing sheet and a method for manufacturing a semiconductor device.

### BACKGROUND

Conventionally, as disclosed in, for example, Japanese Patent Application Laid-Open Publication No. 2018-195805, a technique has been proposed in which a thermocompression-bonding film, having a base layer made of polyolefin but not having an adhesive layer formed of an adhesive agent or the like, is attached to a surface of a workpiece such as a semiconductor wafer by thermocompression bonding. Use of such a thermocompression-bonding film may be advantageous because, after the film is removed from the surface of the workpiece, adhesive agent is less likely to remain.

However, according to studies by the inventor of the present disclosure, in conventional techniques including the technique disclosed in the above-referenced publication, tight bonding of the thermocompression-bonding film to the workpiece by thermocompression may cause an extremely small portion of elements composing the film to remain on the workpiece side.

### SUMMARY

An object of the present disclosure is to provide a wafer-processing sheet and a method for manufacturing a semiconductor device that may inhibit some elements forming a wafer-processing sheet from reaching a wafer, thereby achieving cleanness of the wafer.

According to one aspect of the present disclosure, a wafer-processing sheet includes a water-soluble resin layer formed of a water-soluble resin, and a base layer formed of a resin sheet covering one side of the water-soluble resin layer and having tackiness on a surface thereof on a side toward the water-soluble resin layer under a predetermined condition.

Optionally, the base layer may be larger than the water-soluble resin layer in a plan view and protrude from an entire outer periphery of the water-soluble resin layer.

Optionally, the wafer-processing sheet may have (exert) tackiness by applying thermocompression.

Optionally, a thickness of the water-soluble resin layer may be 100 μm or less.

Optionally, a dissolution rate of the water-soluble resin to be dissolved in water at a first temperature between 0° C. and 35° C., inclusive, may be ⅕ or less of a dissolution rate of the water-soluble resin to be dissolved in water at a second temperature between 35° C. and 100° C., inclusive.

According to another aspect of the present disclosure, a method includes fixing a wafer-processing sheet, which includes a water-soluble resin layer formed of a water-soluble resin and a base layer formed of a resin sheet covering one side of the water-soluble resin layer and having tackiness on a surface thereof on a side toward the water-soluble resin layer under a predetermined condition, to a wafer in a plate shape including a device region in which devices are formed and an outer peripheral excess region surrounding the device region, in an orientation such that a side of the wafer-processing sheet having the water-soluble resin layer faces the wafer; processing the wafer while supplying a liquid including water to the wafer; after the processing, separating at least the base layer of the wafer-processing sheet from the wafer; and after the separating, washing a surface of the wafer, onto which the wafer-processing sheet had been fixed, with a liquid including water. In this method, optionally, the base layer may be larger than the water-soluble resin layer in a plan view and protrude from an entire outer periphery of the water-soluble resin layer.

Optionally, the water-soluble resin layer may be larger than the device region in a plan view, and the device region may be covered with the water-soluble resin layer by the fixing of the wafer-processing sheet.

Optionally, the processing may include thinning the wafer by grinding.

Optionally, the processing may include dividing the wafer along predetermined dividing lines set on the wafer and singularizing the wafer.

According to the above aspects, a wafer-processing sheet and a method for manufacturing a semiconductor device, by which some elements forming the wafer-processing sheet may be inhibited from reaching the wafer, enabling achieving cleanness of the wafer, are provided.

### BRIEF DESCRIPTION OF THE DRAWINGS

FIGS. 1A-1B are diagrams to illustrate a configuration of a wafer-processing sheet.

FIG. 2 is a diagram to illustrate a configuration of a wafer.

FIGS. 3A-3B are diagrams to illustrate a step to fix the wafer-processing sheet to the wafer (sheet-fixing step, fixing).

FIG. 4 is a diagram to illustrate a processing step (processing).

FIGS. 5A-5B are diagrams to illustrate a separating step (separating) and a washing step (washing).

### DESCRIPTION OF EMBODIMENTS

### Terminology and Definitions

The term “wafer-processing sheet” in the present disclosure may optionally be read as, for example, “wafer-processing tape,” “wafer-processing film,” “wafer-processing member,” “wafer-processing auxiliary sheet,” “wafer-processing auxiliary tape,” “wafer-processing auxiliary film,” or “wafer-processing auxiliary member.” Further, the term “wafer” in the “wafer-processing sheet” may mean a general workpiece that may be processed by various processing apparatuses, and may be replaced with “processed object,” “object to be processed,” or “workpiece.” Processing of a wafer by a processing apparatus may include, for example, laser processing in which the wafer is processed with a laser beam, cutting processing in which the wafer is cut with an annular cutting blade, polishing processing in which the wafer is polished with a polishing pad, and grinding processing in which the wafer is ground with a grindstone. Furthermore, a processing step of the wafer by the processing apparatus may include a thinning step of thinning the wafer by grinding, or a singularizing step of dividing the wafer along predetermined dividing lines set on the wafer and singularizing the wafer.

In the present disclosure, a term such as “xx step” may be interpreted (equated) as “xx-ing.” For example, the term “fixing step (sheet-fixing step)” may be read as “fixing,” the term “processing step” may be read as “processing,” the term “separating step” may be read as “separating,” the term “washing step” may be read as “washing,” the term “thinning step” may be read as “thinning,” and the term “singularizing step” may be read as “singularizing.”

The term “wafer” in the present disclosure may mean, for example, a “semiconductor wafer” which is a substrate of a semiconductor integrated circuit. The semiconductor wafer may be actualized as a disk obtained by slicing a single crystal ingot grown from silicon (Si), silicon carbide (SiC), or the like into a thin plate of an appropriate thickness. Further, the term “wafer” is not necessarily limited to semiconductor components but may mean a wafer-shaped workpiece made of various materials such as silicon (Si), silicon carbide (SiC), glass, or resin. In the present disclosure, the single term “wafer” may be used to express a broad concept including not only semiconductor wafers but also wafer-shaped workpieces, which are not limited to semiconductor components. Furthermore, the terms “wafer” and “semiconductor wafer” may be replaced with each other (in particular, when a semiconductor wafer is referred to, it may even be interpreted as a wafer-shaped workpiece not limited to semiconductor components).

The “wafer-processing sheet” in the present disclosure is configured to be attached to at least a surface on one side (at least one side) of a wafer when the wafer is processed in a processing apparatus and has a function to protect the attached surface of the wafer, in particular, a device region (chip region). After the wafer is processed through in the processing apparatus, the wafer-processing sheet is removed from the wafer.

A “water-soluble resin layer” in the present disclosure has properties and functions such that, even in a case where some residual elements (residues) are produced from a base layer or from the wafer-processing sheet, the residual elements (residues) do not reach the wafer (in particular, the device region) so that the wafer (in particular, the device region) is prevented from directly contacting the base layer (a transfer origin and a transfer destination of the residual elements (residues) are isolated or separated from each other). Further, after the above role of preventing direct contact (isolating, separating) is accomplished, the “water-soluble resin layer” may be removed (washed off) from the wafer when being washed with cleaning water (a liquid including water). In other words, in a case where the water-soluble resin layer (which may be interpreted as the residual elements (residues) when the water-soluble resin layer remains on the wafer) or other residual elements (residues) caused from the base layer remain on the wafer or on the water-soluble resin layer, those may be reliably removed (washed off) from the wafer.

The “base layer” in the present disclosure is formed of a resin sheet, which covers one side of the above water-soluble resin layer (for example, a surface opposite to a wafer-facing surface that faces the wafer) and has (exerts) tackiness on a surface that faces the above wafer-soluble resin layer (for example, the wafer-facing surface) under a predetermined condition. “Tackiness” refers to a force (initial adhesive strength, instantaneous adhesive strength) that has a property of adhering to a wafer (adherend) in a short time by merely lightly touching (approaching) the wafer (adherend), and represents a concept including, for example, adhesion or thermocompression bonding force. Moreover, falling “under a predetermined condition” may vary depending on the cause that generates the tackiness (mechanism for attaching the wafer-processing sheet to the wafer). Specifically, in a case where an adhesive force is used as the cause, exposing an adhesive surface of the base layer and causing the sheet to be located close to the wafer (adherend) falls “under a predetermined condition.” In a case where thermocompression bonding force is used as the cause, causing the thermocompression bonding surface of the base layer to be located close to the wafer (adherend) and heated falls “under a predetermined condition.” The base layer may not need to have tackiness (adhesive force or thermocompression bonding force) at all time, as long as it exerts the tackiness “under a predetermined condition” at the time when being attached to the wafer. As such, the base layer has flexibility in mechanisms for generating tackiness, allowing various design modifications.

In the present disclosure, the “base layer” formed of the resin sheet having (exerting) tackiness in a broad sense includes those in which, bonding or adhesive agent may remain using its bonding force or adhesive force even after removal of the wafer-processing sheet. Further, the “base layer” formed of the resin sheet having (exerting) tackiness in a narrow sense excludes those that may leave bonding or adhesive agent remaining due to its bonding or adhesive force, and does not include those that may leave bonding or adhesive agent remaining after removal of the wafer processing sheet due to their thermocompression bonding force (however, possibility of generating residual elements (residues) remains).

The base layer may be larger than the water-soluble resin layer in a plan view and may protrude outward from an entire outer periphery of the water-soluble resin layer. In other words, with regard to the wafer-facing surface of the wafer-processing sheet, the water-soluble resin layer may be located in an area on the wafer-facing surface (for example, a central area), and the base layer (resin sheet having tackiness) may be located in another area (for example, a peripheral area) on the wafer-facing surface. For example, when the wafer and the wafer-facing surface are in a same circular (substantially circular) shape having a same contour (or substantially a same contour), the water-soluble resin layer may form a circular (or substantially circular) portion on a central side of the wafer-facing surface, and the base layer may form an annular (substantially annular) portion in an area toward a periphery of the wafer-facing surface. In this case, when the wafer-facing surface of the wafer-processing sheet is attached to the wafer, the area toward the peripheries (outer peripheral excess region) of the wafer and the wafer-facing surface are adhered to each other by the tackiness of the base layer, and a closed space (sealed space) on the central side is loaded (filled) with the water-soluble resin layer. Furthermore, in a case where a device region (chip region) is formed at the central side of the wafer, the water-soluble resin layer loaded in (filling) the closed space (sealed space) at the center of the wafer-facing surface may protect the device region highly effectively (preventing water supplied for processing the wafer and the residual elements (residues) produced from the base layer or the wafer-processing sheet from reaching the device region (chip region) reliably).

The wafer-processing sheet is not limited to a laminated structure where two layers of the water-soluble resin layer and the base layer are laminated, but may include an additional or alternative layer being laminated. For example, the wafer-processing sheet may have a PET (Poly Ethylene Terephthalate) layer located on a surface on a side opposite to the water-soluble resin layer of the base layer (i.e., the base layer may be located between the water-soluble resin layer and the PET layer).

The “water-soluble resin (layer)” in the present disclosure is formed of a heated-water soluble film, that is, a resin (layer) exerting a property, in which solubility (dissolution rate) in a relatively high-temperature liquid (heated water) is higher than solubility (dissolution rate) in a relatively low-temperature liquid (water). As an example of the heated-water soluble film, the water-soluble resin may have a dissolution rate of, when dissolved in water of a first temperature between 0° C. and 35° C., inclusive, ⅕ or less of the dissolution rate when dissolved in water at a second temperature between 35° C. and 100° C., inclusive. In this case, water at 35° C. may be categorized into either the water at the first temperature or the water at the second temperature. In other words, for example, water at the first temperature may be defined as water at 0° C. or higher and lower than 35° C., and water at the second temperature may be defined as water at 35° C. or higher and 100° C. or lower. For another example, water at the first temperature may be defined as water at 0° C. or higher and 35° C. or lower, and water at the second temperature may be defined as water at higher than 35° C. and 100° C. or lower.

### Configuration of Wafer-Processing Sheet

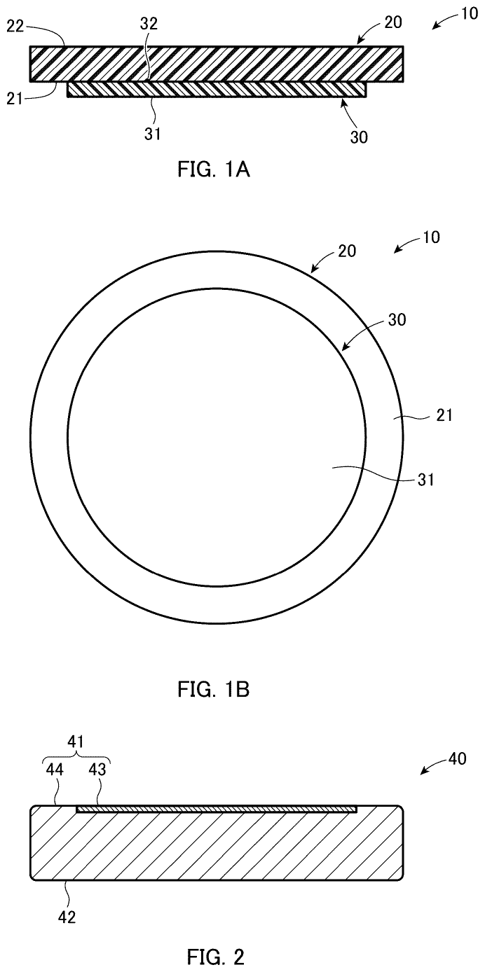

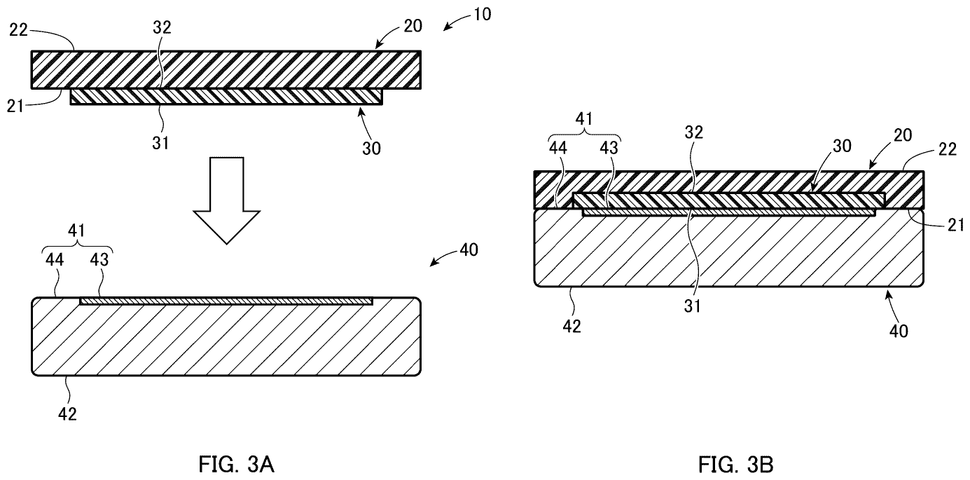

Referring to FIGS. 1A-1B, 2, and 3A-3B, a configuration of a wafer-processing sheet 10 is described. FIGS. 1A and 1B are diagrams to illustrate a configuration of the wafer-processing sheet 10. FIG. 2 is a diagram to illustrate a configuration of a wafer 40. FIGS. 3A and 3B are diagrams to illustrate a step to fix the wafer-processing sheet 10 to the wafer 40 (sheet-fixing step).

The wafer-processing sheet 10 includes a base layer 20 and a water-soluble resin layer 30.

The base layer 20 forms a functional layer of a so-called thermocompression bonding sheet and has (exerts) tackiness by applying thermocompression. The base layer 20 has a first surface 21 and a second surface 22 that are located on sides opposite to each other, where the first surface 21 is a surface to face the wafer 40, and the second surface 22 is a surface not to face the wafer 40 (a surface on the opposite side from the wafer 40).

The base layer 20 is formed of a resin sheet having (exerting) tackiness on the first surface 21 (surface on a side toward the water-soluble resin layer 30) under a predetermined condition. In other words, by locating the first surface (thermocompression bonding surface) 21 of the base layer 20 close to the wafer 40 and heating, tackiness is generated on the first surface (thermocompression bonding surface) 21 of the base layer 20, thereby enabling the base layer 20 or the wafer-processing sheet 10 to be fixed to the wafer 40.

The resin sheet (resin material) that forms the base layer 20 has flexibility, allowing various design modifications, and may be configured, for example, as below. That is, the resin sheet (resin material) composing the base layer 20 may be formed of a plastic material such as a polymer including, for example, polyolefin, polyethylene (PE), or polypropylene (PP). For example, a polyolefin film may be, when in a heated state (when heated to a temperature in a range between 60° C. and 150° C.), stretched pliably and has flexibility. Therefore, the base layer 20 may be fitted to an attachable surface of the wafer 40 (for example, by absorbing topography) to exert tackiness (for fixing). Further, the tackiness exerted by the base layer 20 on the wafer 40 may be caused by, in addition to the base layer 20 adapted (fitted) to the attachable surface, intermolecular force due to the close contact.

The water-soluble resin layer 30 is formed of (includes) a water-soluble resin and has a first surface 31 and a second surface 32 that are located on sides opposite to each other. The first surface 31 forms a surface that faces and protects the wafer 40 (more specifically, a device region 43 on a first surface 41 which is described later), and the second surface 32 of the water-soluble resin layer 30 forms a surface to be fixed to, joined to, or applied to the first surface 21 of the base layer 20. In other words, one side (the second surface 32) of the water-soluble resin layer 30 is covered with the first surface 21 of the base layer 20.

Meanwhile, timing and methods for integrating the base layer 20 and the water-soluble resin layer 30 may be arranged flexibly, allowing various design modifications. For example, at a stage before fixing the wafer-processing sheet 10 to the wafer 40, the water-soluble resin layer 30 may be fixed or joined to the first surface 21 of the base layer 20 in advance (both the base layer 20 and the water-soluble resin layer 30 being in a dry state), or the water-soluble resin layer 30 may be applied to the first surface 21 of the base layer 20 and subsequently dried. For another example, at a stage immediately before fixing the wafer-processing sheet 10 to the wafer 40, the water-soluble resin layer 30 may be applied to the first surface 21 of the base layer 20 (in this case, the water-soluble resin layer 30 may be in a wet state). Further, in a broader sense, at a stage immediately before fixing the wafer-processing sheet 10 to the wafer 40, the water-soluble resin layer 30 may be applied to a desired portion of the wafer 40 (for example, the device region 43 on the first surface 41 described later), and subsequently, the base layer 20 may be fixed or joined thereover by thermocompression bonding.

A thickness of the water-soluble resin layer 30 may be 100 μm or less and may be set sufficiently smaller than a thickness of the base layer 20. In FIGS. 1A and 3A, the thickness (a protruding amount from the base layer 20) of the water-soluble resin layer 30 is exaggerated to be large; however, it is an expression of a state in which a thin water-soluble resin layer 30 is placed (applied) on the first surface 21 of the base layer 20 in practice. Therefore, a height difference between a present portion where the water-soluble resin layer 30 is present and an absent portion where the water-soluble resin layer 30 is absent is not notably large. Accordingly, tackiness of the base layer 20 may exert not only in the absent portion of the water-soluble resin layer 30 but also in the present portion of the water-soluble resin layer 30. In other words, the water-soluble resin layer 30 does not necessarily have (exert) tackiness, as long as it may exert a protective function (barrier function, shielding function) for the wafer 40 (device region 43) as described later.

The base layer 20 is larger than the water-soluble resin layer 30 in a plan view and protrudes from an entire outer periphery of the water-soluble resin layer 30. More specifically, with regard to a wafer-facing surface of a wafer-processing sheet 10 (surface including the first surface 21 of the base layer 20 and the first surface 31 of the water-soluble resin layer 30), the water-soluble resin layer 30 (the first surface 31) is located in a circular (substantially circular) area on a central side, and the base layer 20 (the first surface 21) is located in an annular (substantially annular) area on a peripheral side.

The water-soluble resin layer 30 may be, for example, a water-soluble thermoplastic resin (in a wet state), of which solubility in water varies largely by temperature, and may be obtained by molding such a thermoplastic resin into a film having an any selected thickness (for example, 100 μm or less). The thermoplastic resin forming the water-soluble resin layer 30 may be, for example, PVA (polyvinyl alcohol) with a high degree of saponification. PVA is less soluble in low-temperature water as the degree of saponification thereof increases (has a property as a heated-water soluble film). In this context, the degree of saponification of the PVA is preferably 97% or higher when a degree of polymerization of the PVA is 600 or higher and lower than 1700, and preferably 96% or higher when the degree of polymerization of the PVA is 1700 or higher.

The PVA used for the water-soluble resin layer 30 may include other monomer units within a range in which the above-described characteristics are not lost. The monomer units that may be contained in the PVA may include, for example, α-olefins such as ethylene, propylene, 1-butene, isobutene, and 1-hexene; acrylic acid and its salts, and acrylic acid esters such as methyl acrylate, ethyl acrylate, n-propyl acrylate, i-propyl acrylate, n-butyl acrylate, i-butyl acrylate, t-butyl acrylate, 2-ethylhexyl acrylate, dodecyl acrylate, and octadecyl acrylate; methacrylic acid and its salts, and methacrylic acid esters such as methyl methacrylate, ethyl methacrylate, n-propyl methacrylate, i-propyl methacrylate, n-butyl methacrylate, i-butyl methacrylate, t-butyl methacrylate, 2-ethylhexyl methacrylate, dodecyl methacrylate, and octadecyl methacrylate; acrylamide and acrylamide derivatives such as N-methylacrylamide, N-ethylacrylamide, N,N-dimethylacrylamide, diacetoneacrylamide, acrylamidopropanesulfonic acid and its salts, acrylamidopropyldimethylamine and its salts, and N-methylolacrylamide and its derivatives; methacrylamide and methacrylamide derivatives such as N-methylmethacrylamide, N-ethylmethacrylamide, methacrylamidopropanesulfonic acid and its salts, methacrylamidopropyldimethylamine and its salts, and N-methylolmethacrylamide and its derivatives; N-vinylamides such as N-vinylpyrrolidone, N-vinylformamide, and N-vinylacetamide; allyl ethers having polyalkylene oxide in the side chain; vinyl ethers such as methyl vinyl ether, ethyl vinyl ether, n-propyl vinyl ether, i-propyl vinyl ether, n-butyl vinyl ether, i-butyl vinyl ether, t-butyl vinyl ether, dodecyl vinyl ether, and stearyl vinyl ether; nitriles such as acrylonitrile and methacrylonitrile; halogenated vinyl compounds such as vinyl chloride, vinylidene chloride, vinyl fluoride, and vinylidene fluoride; allyl compounds such as allyl acetate and allyl chloride; maleic acid and its salts or esters; vinylsilyl compounds such as vinyltrimethoxysilane; isopropenyl acetate, or the like.

Optionally, the thermoplastic resin used for the water-soluble resin layer 30 may have a plasticizer added. In other words, the thermoplastic resin used for the water-soluble resin layer 30 may include, in addition to the above PVA, a plasticizer. By adding the plasticizer to the water-soluble resin layer 30, the water-soluble resin layer 30 may deform more readily to adapt to the shape of the wafer 40 (particularly the device region 43 described later), whereby the water-soluble resin layer 30 may be fitted more securely to the wafer 40 (particularly the device region 43 described later). Among various plasticizers, a water-soluble plasticizer may be used preferably. This is because, by adding the water-soluble plasticizer in the water-soluble resin layer 30, the water-soluble plasticizer, and thus the water-soluble resin layer 30, may be suitably (reliably, easily) removed (washed off) without remaining on the wafer 40 (particularly the device region 43 described later).

As such a plasticizer, those generally used as plasticizers for PVA may be used without limitation. Specific plasticizers include, for example, polyhydric alcohols such as glycerin, diglycerin, diethylene glycol, triethylene glycol, propylene glycol, dipropylene glycol, trimethylolpropane, pentaerythritol, and 1,3-butanediol; polyethers such as polyethylene glycol and polypropylene glycol; polyvinyl amides such as polyvinylpyrrolidone; amide compounds such as N-methylpyrrolidone and dimethylacetamide; and compounds obtained by adding ethylene oxide to polyhydric alcohols such as glycerin, pentaerythritol, sorbitol, or water, or the like. Note that solely one of these plasticizers may be added, or two or more may be added in the water-soluble resin layer 30.

Furthermore, these plasticizers may be added in the water-soluble resin layer 30 not only for the purpose of enhancing adaptability to the wafer 40 (particularly the device region 43 described later) but also for a purpose of enhancing water solubility. In order to enhance the water solubility of the water-soluble resin layer 30, glycerin, diglycerin, diethylene glycol, triethylene glycol, propylene glycol, dipropylene glycol, trimethylolpropane, polyethylene glycol, polyvinylpyrrolidone, or the like may be preferably used as the plasticizer. In order to suppress deterioration of water solubility of the water-soluble resin layer 30 due to bleed-out of the plasticizer, glycerin, diglycerin, trimethylolpropane, polyethylene glycol, polyvinylpyrrolidone, or the like may be used as the plasticizer.

The water-soluble resin layer 30 configured with combination of the thermoplastic resin and the plasticizer as described above preferably has a property as a heated-water soluble film, in which a dissolution rate when dissolved in water at the first temperature between 0° C. and 35° C., inclusive, is ⅕ or less of a dissolution rate when dissolved in water at the second temperature between 35° C. and 100° C., inclusive. The water at the first temperature may be defined as, for example, water at 0° C. or higher and lower than 35° C., and the water at the second temperature may be defined as water at 35° C. or higher and 100° C. or lower. For another example, the water at the first temperature may be defined as water at 0° C. or higher and 35° C. or lower, and the water at the second temperature may be defined as water at higher than 35° C. and 100° C. or less.

The above conditional expressions indicate that the water-soluble resin layer 30 has higher solubility (dissolution rate) in a liquid at the second temperature (heated water), which is relatively high, than in a liquid at the first temperature(water), which is relatively low. Therefore, for example, by setting water to be supplied in a processing step, which will be described later, as a liquid (water) at the first temperature, even if the supplied water at the first temperature contacts the water-soluble resin layer 30, the water-soluble resin layer 30 may exert its protective function (barrier function, shielding function) for the wafer 40 (device region 43) as described later without (substantially) dissolving. On the other hand, by setting water to be supplied in a washing step, which will be described later, as a liquid at the second temperature (heated water), the water-soluble resin layer 30, which has accomplished exerting its protective function (barrier function, shielding function) for the wafer 40 (device region 43) as described later and has become unnecessary, may be dissolved and removed (washed off) simply and promptly by the water at the second temperature.

In order to easily exhibit such a difference in solubility (dissolution rate), the first temperature of the water is preferably between 10° C. and 30° C., inclusive, and more preferably, between 15° C. and 30° C., inclusive. Further, the water at the second temperature is preferably between 40° C. and 70° C., inclusive, and more preferably, between 45° C. and 60° C., inclusive.

The wafer 40 may be, for example, a substantially disk-shaped substrate made of a material such as Si (silicon), SiC (silicon carbide), GaN (gallium nitride), GaAs (gallium arsenide), semiconductor, or the like, or a material such as sapphire, glass, quartz, or the like. The glass may be, for example, alkali glass, alkali-free glass, soda-lime glass, lead glass, borosilicate glass, quartz glass, or the like.

The wafer 40 has the first surface 41 and a second surface 42 that are located on sides opposite to each other, where the first surface 41 is a surface to face the wafer-processing sheet 10 (the first surface 21 of the base layer 20 and the first surface 31 of the water-soluble resin layer 30), and the second surface 42 is a surface not to face the wafer-processing sheet 10 (surface on the opposite side from the wafer-processing sheet 10).

The first surface 41 of the wafer 40 is partitioned into the device region (chip region) 43 formed in a circular (substantially circular) area on a central side, and an outer peripheral excess region 44 formed in an annular (substantially annular) area on a peripheral side. In other words, the first surface 41 of the plate-shaped (disk-shaped) wafer 40 includes the device region 43, in which devices are formed, and the outer peripheral excess region 44 surrounding the device region 43.

Although not illustrated, the device region 43 is partitioned by a plurality of predetermined dividing lines (streets) arranged in a grid, and in each region partitioned by the dividing lines, a device such as an IC (Integrated Circuit), an LSI (Large Scale Integration), an LED (Light Emitting Diode), or the like is formed. Processing (processing step) of the wafer 40 in the present embodiment may include, for example, thinning (step) in which (the second surface 42 of) the wafer 40 is thinned by grinding, and/or singularizing (step) in which (the device region 43 on) the wafer 40 is singularized by dividing along the predetermined dividing lines set in the wafer 40.

An arrangement balance between the device region 43 and the outer peripheral excess region 44 on the first surface 41 of the wafer 40 may be determined flexibly, allowing various design modifications. For example, an annular (substantially annular) reference line located at 1 mm to 5 mm inside from the outermost periphery of the first surface 41 of the wafer 40 may be set as a reference line, and an inside of the reference line may be defined as the device region 43, and an outside of the reference line may be defined as the outer peripheral excess region 44.

In the present embodiment, the wafer-processing sheet 10 and the wafer 40 form the same circular (substantially circular) shape having the same contour (substantially the same contour) in a plan view. With regard to the wafer-facing surface of the wafer-processing sheet 10, the first surface 31 of the water-soluble resin layer 30 corresponds to the device region 43 in the wafer 40, and the first surface 21 of the base layer 20 (an outer peripheral exposed portion of the first surface 31 of the water-soluble resin layer 30) corresponds to the outer peripheral excess region 44 of the wafer 40. In the plan view, the first surface 31 of the water-soluble resin layer 30 at least covers (coats) the device region 43 in the wafer 40 and has the shape identical to, or slightly larger than, the device region 43 in the wafer 40.

Therefore, throughout the time before and after fixing the wafer-processing sheet 10 to the wafer 40, or at least after fixing the wafer-processing sheet 10 to the wafer 40, the water-soluble resin layer 30 is larger than the device region 43 in the wafer 40 in a plan view. By a sheet-fixing step which is described later, the device region 43 in the wafer 40 is covered with the water-soluble resin layer 30. Further, the base layer 20 (the outer peripheral exposed portion of the water-soluble resin layer 30) is fixed to the outer peripheral excess region 44 of the wafer 40 by thermocompression bonding (fixed by tackiness); therefore, a portion on an inner peripheral side of the base layer 20 with respect to the outer peripheral side is loaded (filled) with the water-soluble resin layer 30, whereby the water-soluble resin layer 30 protects (barriers, shields) the device region 43 in the wafer 40.

First, by the protective function (barrier function, shielding function) of the base layer 20, which is bonded (fixed) by thermocompression to the outer peripheral excess region 44 of the wafer 40, water to be supplied in the processing step be described later is prevented from reaching the water-soluble resin layer 30. In an unlikely case where a portion of the water supplied in the processing step described later passes through the base layer 20 and enters the inner peripheral side, by the protective function (barrier function, shielding function) of the water-soluble resin layer 30, the portion of the water is prevented from reaching the device region 43 in the wafer 40. As such, by the doubled protective function (barrier function, shielding function) of the base layer 20 and the water-soluble resin layer 30 of the wafer-processing sheet 10, water supplied in the processing step described later is reliably prevented from reaching the device region 43 in the wafer 40.

Moreover, by the protective function (barrier function, shielding function) of the water-soluble resin layer 30, even in a case where the residual elements (residues) are produced from the base layer 20 or the wafer-processing sheet 10 while the wafer-processing sheet 10 and the wafer 40 are in the fixed state, the wafer 40 (the device region 43) is prevented from directly contacting the base layer 20 (a transfer origin and a transfer destination of the residual elements (residues) are isolated or separated from each other) so that the residual elements (residues) do not reach the wafer 40 (the device region 43). Note that, while the wafer 40 is being washed during the washing step which will be described later, the water-soluble resin layer 30 that has accomplished the above role of preventing direct contact (isolation, separation) may be removed (washed off) from the wafer 40.

Meanwhile, the outer peripheral excess region 44 of the wafer 40 is not protected (barriered, shielded) by the water-soluble resin layer 30; therefore, the residual elements (residues) from the base layer 20 or the wafer-processing sheet 10 may adhere thereto. However, since the outer peripheral excess region 44 is irrelevant to the functions of the wafer 40 (for example, electrical characteristics as a semiconductor wafer), the residual elements (residues) due not affect adversely. This is similarly true when bonding force or adhesive force is used as the mechanism of tackiness of the wafer-processing sheet 10 (the base layer 20), and even in a case where a bonding or adhesive agent remains in the outer peripheral excess region 44 of the wafer 40, the remaining bonding or adhesive agent does not affect adversely.

### Method for Manufacturing Semiconductor Device

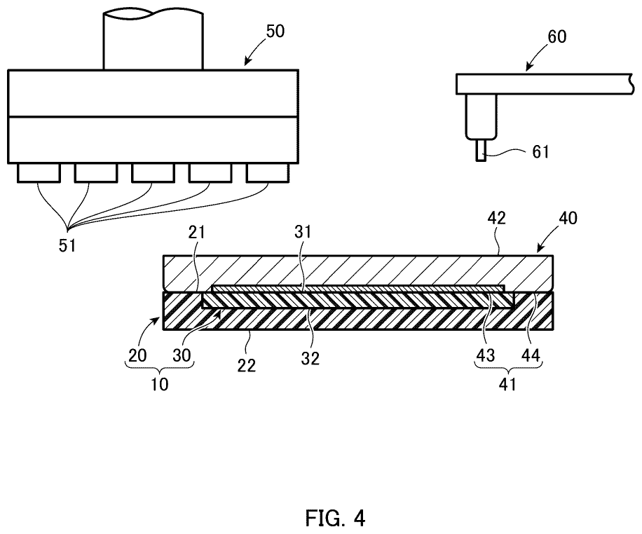

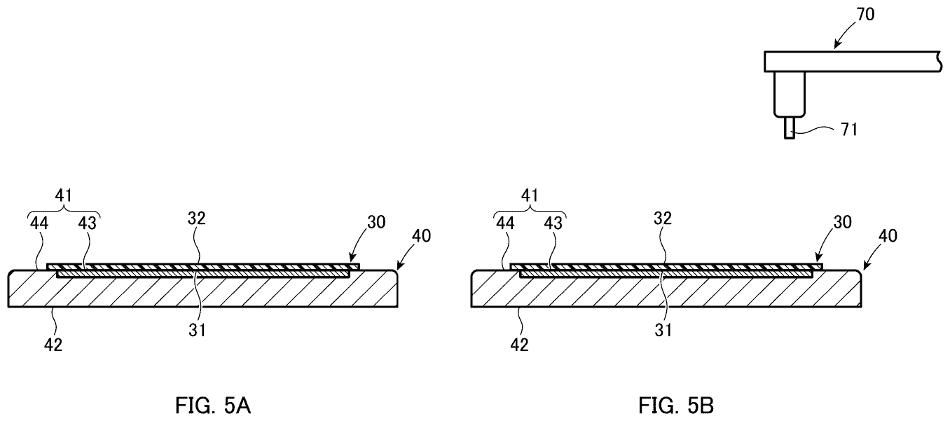

Next, with reference to FIGS. 3A-3B, 4, and 5A-5B, a method for manufacturing a semiconductor device according to the present embodiment will be described. FIGS. 3A-3B are diagrams to illustrate the sheet-fixing step. FIG. 4 is a diagram to illustrate the processing step. FIGS. 5A-5B are diagrams to illustrate the separating step and the washing step.

### Sheet-Fixing Step (Fixing)

First, the wafer-processing sheet 10 in the configuration described above, including the water-soluble resin layer 30 formed of the water-soluble resin and the base layer 20, which is formed of a resin sheet to cover one side (the second side 32) of the water-soluble resin layer 30 and has (exerts) tackiness on the side toward the surface (the first surface 21) of the water-soluble resin layer 30 under the predetermined condition, where the base layer 20 is larger than the water-soluble resin layer 30 to protrude from the entire outer periphery of the water-soluble resin layer 30 in a plan view, is prepared. Further, the plate-shaped wafer 40 in the configuration described above, that is, the wafer 40 including the device region 43, in which devices are formed, and the outer peripheral excess region 44 surrounding the device region 43, is prepared. Next, the wafer-processing sheet 10 is fixed to the plate-shaped wafer 40 in an orientation such that the side of the wafer-processing sheet 10 having the water-soluble resin layer 30 faces the wafer 40.

More specifically, the wafer-facing surface (the first surface 21 of the base layer 20 and the first surface 31 of the water-soluble resin layer 30) of the wafer-processing sheet 10 is located to face the first surface 41 (the device region 43 and the outer peripheral excess region 44) of the wafer 40. In this instance, the first surface 31 of the water-soluble resin layer 30 is aligned with the device region 43, and the first surface 21 of the base layer 20 (the outer peripheral exposed portion from the first surface 31 of the water-soluble resin layer 30) is aligned with the outer peripheral excess region 44. Next, the wafer-facing surface (the first surface 21 of the base layer 20 and the first surface 31 of the water-soluble resin layer 30) of the wafer-processing sheet 10 is located close to the first surface 41 (the device region 43 and the outer peripheral excess region 44) of the wafer 40 and pressed against (fitted tightly with) each other (see FIG. 3A). In this pressed (tightly fitted) state, by heating at least one of the wafer-processing sheet 10 and the wafer 40 with a heater (not shown), thermocompression bonding force (tackiness) is generated in the wafer-processing sheet 10 (the base layer 20), thereby fixing the wafer-processing sheet 10 and the wafer 40 to each other (see FIG. 3B). For convenience of illustration herein, FIGS. 3A-3B illustrate the water-soluble resin layer 30 in the wafer-processing sheet 10, which melts and spreads in a radial direction (right-left direction in FIGS. 3A-3B) to cover up to the outer diameter side (a part of the outer peripheral excess region 44) with respect to the peripheral edge of the device region 43 in the wafer 40, and the base layer 20 that surrounds the outer peripheral side of the water-soluble resin layer 30, as the process (thermocompression bonding step) proceeds from FIG. 3A to FIG. 3B.

In the sheet-fixing step, a heater roller (not shown) may be used for thermocompression bonding to fix the wafer-facing surface of the wafer-processing sheet 10 to the first surface 41 of the wafer 40. Optionally, the wafer-processing sheet 10 not having the same size as the wafer 40 may be attached to the wafer 40, and thereafter, the wafer-processing sheet 10 may be cut according to the shape of the wafer 40. For example, a wafer-processing sheet 10 larger than the wafer 40 in a plan view may be prepared, and after attaching the wafer-processing sheet 10 to the wafer 40 so as to cover the wafer 40 and protrude to the peripheral portion, the excess portion (portion protruding from the wafer 40 in the plan view) of the wafer-processing sheet 10 may be cut.

### Processing Step (Processing)

The wafer 40 is processed while a liquid including water is being supplied thereto. FIG. 4 illustrate a thinning step (thinning step by back grinding), in which the wafer 40 is ground and thinned, as the processing step. Specifically, an assembly of the wafer-processing sheet 10 and the wafer 40 formed in the sheet-fixing step is rotated (inverted) so that the second surface 42 of the wafer 40, which is the surface to be processed, faces upward in FIG. 4, and a grinding apparatus (thinning apparatus) 50 as a processing apparatus and a water supply apparatus 60 are located to face the second surface 42. Next, while supplying the liquid including water (for example, water at the first temperature, water at 20° C.) from a nozzle 61 of the water supply apparatus 60 to the second surface 42 of the wafer 40, the second surface 42 of the wafer 40 is ground by a grinder (grinding pad) 51 of the grinding apparatus 50 to thin the wafer 40 (see FIG. 4, where the wafer 40 having been thinned is recognizable compared to FIG. 3B).

In this processing step, the liquid including water (for example, water at the first temperature) supplied from the water supply apparatus 60 is prevented from reaching the device region 43 in the wafer 40 by the double protective function (barrier function, shielding function) of the base layer 20 and the water-soluble resin layer 30 of the wafer-processing sheet 10. Further, even in a case where residual elements (residues) are produced from the base layer 20 or the wafer-processing sheet 10, the water-soluble resin layer 30 protected (barriered, shielded) by the base layer 20 functions to prevent the base layer 20 from directly contacting the wafer 40 (the device region 43), thereby isolating or separating the transfer origin and the transfer destination of the residual elements (residues).

### Separation Step (Separating)

After the above processing step, at least the base layer 20 in the wafer-processing sheet 10 is separated from the wafer 40. More specifically, the assembly of the wafer-processing sheet 10 and the wafer 40 processed (the wafer 40 thinned) in the processing step is rotated (inverted) again so that the wafer-processing sheet 10 (the base layer 20 and the water-soluble resin layer 30) faces upward in the FIG. 4. Next, by holding (pinching) an edge of the base layer 20 in the wafer-processing sheet 10 with a separating apparatus (not shown) and pulling the base layer 20 off (peeling), the base layer 20 in the wafer-processing sheet 10 is separated from the wafer 40 (see FIG. 5A). In this state of the base layer 20 separated, the water-soluble resin layer 30 of the wafer-processing sheet 10 remains, covering the device region 43 in the wafer 40.

### Washing Step (Washing)

After the separation step, the surface (the first surface 41) of the wafer 40 to which the wafer-processing sheet 10 had been fixed is washed with a liquid including water (for example, heated water at the second temperature, heated water at 70° C.). More specifically, a washing apparatus 70 is located to face the first surface 41 of the wafer 40, and the liquid including water (for example, heated water at the second temperature, heated water at 70° C.) is supplied from a nozzle 71 of the washing apparatus 70 to wash the first surface 41 of the wafer 40 (see FIG. 5B). As such, the water-soluble resin layer 30 remaining and covering the device region 43 is removed (washed off) from the wafer 40. As described above, the water-soluble resin layer 30 functions to prevent the base layer 20 from directly contacting the wafer 40 (the device region 43) (isolate or separate the transfer origin and the transfer destination of the residual elements (residues)) so as to prevent the residual elements (residues) produced from the base layer 20 or the wafer-processing sheet 10 from reaching the wafer 40 (the device region 43); therefore, after accomplishing the function (the role) thereof, the water-soluble resin layer 30 may be removed (washed off) from the wafer 40.

### First Modified Example

In the above embodiment (FIG. 4), the thinning step (thinning step by back grinding) to thin the wafer 40 by grinding has been described as an example of the processing step. However, the processing step is not limited to the thinning step but may be applied, for example, to a singularizing step for singularizing the wafer 40 by dividing along the predetermined dividing lines set in the wafer 40 (singularizing step by dicer full cut, or a singularizing step in which thinning and chip dividing are performed simultaneously by grinding after dicer half cut). Also in the singularizing step, cut-processing (processing with a cutting blade) may be performed while supplying a liquid including water (for example, water at the first temperature, water at 20° C.) to the wafer 40. In such a case, the water is supplied and the wafer 40 is cut from the side of the first surface 41, in other words, from the side on which the wafer-processing sheet 10 was fixed, and similarly, by the double protective function (barrier function, shielding function) of the base layer 20 and the water-soluble resin layer 30, the water and the residual elements (residues) are prevented from reaching the device region 43 in the wafer 40. Furthermore, the processing step in the present embodiment is applicable to all kinds of processing steps other than the thinning step (thinning step by back grinding) and the singularizing step (singularizing step by dicer full cut, or singularizing step in which thinning and chip dividing are performed simultaneously by grinding after dicer half cut).

### Second Modified Example

The above embodiment illustrated and described a case in which the base layer is larger than the water-soluble resin layer in a plan view and protrudes from the entire outer periphery of the water-soluble resin layer. However, the base layer may have, in a plan view, the same contour as the water-soluble resin layer or a portion protruding inward to the inner peripheral side thereof (at least a part of the water-soluble resin layer may be exposed on a lateral surface). In this arrangement, the protective function (barrier function, shielding function) by the base layer may be partially weakened; however, as long as the water-soluble resin layer covers the device region in the wafer, the protective function (barrier function, shielding function) by the water-soluble resin layer is ensured (guaranteed), so that a certain effect for achieving cleanness of the wafer may be provided.

### Third Modified Example

The above embodiment illustrated and described a case where, with regard to the wafer-facing surface of the wafer-processing sheet, the circular (substantially circular) water-soluble resin layer is located at the central area (central side) of the wafer-facing surface, and the annular (substantially annular) base layer is located in the peripheral area (peripheral side) of the wafer-facing surface. However, the arrangement, forms, or number of the water-soluble resin layer and the base layer on the wafer-facing surface of the wafer-processing sheet may be determined flexibly, allowing various design modifications. For example, in a case where the device region of the wafer is not concentrated solely in the central area (central side) of the wafer but is distributed to the peripheral area (peripheral side) of the wafer, by dividing the water-soluble resin layer into a plurality of layers and dispersedly arranging them in gaps in the base layer, the device regions on the wafer may be uniformly and efficiently protected (barriered, shielded).

As described above, the wafer-processing sheet according to the present embodiment includes a water-soluble resin layer formed of a water-soluble resin, and a base layer formed of a resin sheet covering one side of the water-soluble resin layer and having tackiness on a surface thereof on a side toward the water-soluble resin layer under a predetermined condition.

Further, the method for manufacturing a semiconductor device according to the present embodiment includes a fixing step for fixing a wafer-processing sheet, which includes a water-soluble resin layer formed of a water-soluble resin and a base layer formed of a resin sheet covering one side of the water-soluble resin layer and having tackiness on a surface thereof on a side toward the water-soluble resin layer under a predetermined condition, where the base layer is larger than the water-soluble resin layer in a plan view and protrudes from an entire outer periphery of the water-soluble resin layer, to a wafer in a plate shape, where the wafer includes a device region in which devices are formed and an outer peripheral excess region surrounds the device region, in an orientation such that a side of the wafer-processing sheet having the water-soluble resin layer faces the wafer; a processing step for processing the wafer while supplying a liquid including water to the wafer; a separating step for, after the processing step, separating at least the base layer of the wafer-processing sheet from the wafer; and a washing step for, after the separating step, washing a surface of the wafer, onto which the wafer-processing sheet had been fixed, with a liquid including water.

Accordingly, some of the elements that form the wafer-processing sheet may be prevented from reaching the wafer, thereby achieving cleanness of the wafer.

While an embodiment of the present invention has been described, embodiments of the present disclosure may not necessarily be limited to the configuration described above but may be modified, substituted, or altered in various ways without departing from the spirit of the technical idea of the present disclosure. Furthermore, if the technical idea of the present disclosure may be realized in a different way due to technological progress or other derived technology, it may be implemented with use of the method. Therefore, the claims cover all embodiments that may be included within the scope of the technical idea of the present disclosure.

As described above, the present disclosure may be applied to, for example, a wafer-processing sheet and a method for manufacturing a semiconductor device that may ensure cleanness of a wafer apart from residual elements (residues).

What is claimed is:

1. A wafer-processing sheet comprising:
a water-soluble resin layer formed of a water-soluble resin, and
a base layer formed of a resin sheet covering one side of the water-soluble resin layer and having tackiness on a surface thereof on a side toward the water-soluble resin layer under a predetermined condition.

2. The wafer-processing sheet according to claim 1, wherein the base layer is larger than the water-soluble resin layer in a plan view and protrudes from an entire outer periphery of the water-soluble resin layer.

3. The wafer-processing sheet according to claim 2, wherein the wafer-processing sheet exerts tackiness by applying thermocompression.

4. The wafer-processing sheet according to claim 1, wherein a thickness of the water-soluble resin layer is 100 μm or less.

5. The wafer-processing sheet according to claim 1, wherein a dissolution rate of the water-soluble resin to be dissolved in water at a first temperature between 0° C. and 35° C., inclusive, is ⅕ or less of a dissolution rate of the water-soluble resin to be dissolved in water at a second temperature between 35° C. and 100° C., inclusive.

6. A method for manufacturing a semiconductor device, comprising:
fixing a wafer-processing sheet, the wafer-processing sheet including a water-soluble resin layer formed of a water-soluble resin and a base layer formed of a resin sheet covering one side of the water-soluble resin layer and having tackiness on a surface thereof on a side toward the water-soluble resin layer under a predetermined condition, to a wafer in a plate shape, the wafer including a device region in which devices are formed and an outer peripheral excess region surrounding the device region, in an orientation such that a side of the wafer-processing sheet having the water-soluble resin layer faces the wafer;
processing the wafer while supplying a liquid including water to the wafer;
after the processing, separating at least the base layer of the wafer-processing sheet from the wafer; and
after the separating, washing a surface of the wafer, onto which the wafer-processing sheet had been fixed, with a liquid including water.

7. The method according to claim 6, wherein the base layer is larger than the water-soluble resin layer in a plan view and protrudes from an entire outer periphery of the water-soluble resin layer.

8. The method according to claim 6,
wherein the water-soluble resin layer is larger than the device region in a plan view, and
wherein the device region is covered with the water-soluble resin layer by the fixing of the wafer-processing sheet.

9. The method according to claim 6, wherein the processing includes thinning the wafer by grinding.

10. The method according to claim 6, wherein the processing includes dividing the wafer along predetermined dividing lines set on the wafer and singularizing the wafer.
